(19) United States
(12) Patent Application Publication
(10) Pub. No.: US 2005/0090094 A1
(43) Pub. Date: Apr. 28, 2005

(54) Method of forming a metal pattern for a semiconductor device

(75) Inventors: Jun-Hwan Oh, Incheon-si (KR); Hong-Seong Son, Suwon-si (KR)

Correspondence Address: F. CHAU & ASSOCIATES, LLC, 130 WOODBURY ROAD, WOODBURY, NY, 11797, US

(73) Assignee: SAMSUNG ELECTRONICS CO., LTD.

(21) Appl. No.: 10/970,297

(22) Filed: Oct. 21, 2004

(30) Foreign Application Priority Data
Oct. 22, 2003 (KR) 2003-73942

(51) Int. Cl. H01L 21/8238; H01L 21/4763; H01L 21/311

(52) U.S. Cl. 438/633; 438/631; 438/629; 438/626; 438/695

(57) ABSTRACT

A method of forming a conductive pattern includes preparing a semiconductor substrate having a conductive pattern, forming an interlayer dielectric pattern having an opening exposing the conductive pattern on the semiconductor substrate, forming a metal layer on the interlayer dielectric pattern to fill the opening, wet etching the metal layer, and polishing the metal layer to form a metal pattern filling the opening. The wet etching is done such that a top surface of the interlayer dielectric pattern is not exposed.

### FIELD OF THE INVENTION

The present invention relates to a method of forming a semiconductor device and more specifically to a method of forming a semiconductor device having a conductive pattern.

### BACKGROUND OF THE INVENTION

As compared to aluminum that is conventionally used as an interconnection material, copper has been shown to have superior electrical conductivity while having no electromigration (EM). A low resistance copper makes it possible to minimize problems such as an increase in interconnection resistance caused by high integration densities of semiconductor devices and other problems such as slow down and an increased power consumption of semiconductor devices caused by a resistance-capacitance (RC) delay. As compared to semiconductor devices using aluminum interconnections, a semiconductor device using a copper interconnection requires a small number of interconnection layers. Thus, where copper is used as the interconnection material, the number of interconnection forming processes is reduced to save fabricating costs. In addition, semiconductor devices using copper as the interconnection material have a higher yield than similarly designed semiconductor devices using aluminum interconnections because there is no product failure and process restriction caused by EM.

It is difficult, however, to readily perform a chemical vapor deposition (CVD) process and a dry etching for a copper layer. Thus, there is a desire for another pattern forming method using copper as an interconnection material. A so-called “dual damascene” process has been proposed to overcome the foregoing restrictions of a copper layer. In the dual damascene process, a trench and a via hole are formed through an insulation layer. After copper is stacked to fill the trench and the via hole, the copper layer is etched using a chemical mechanical polishing (CMP) process. Due to the dual damascene process, copper can be used as an interconnection material without performing the CVD process and the dry etching process.

However, where a copper layer is thickly deposited similar to that of a copper layer used in an inductor of a radio frequency (RF) device, the time required for the CMP process increases, thus reducing the productivity of a CMP apparatus. Further, there is a phenomenon resulting from the CMP process in which a surface defect generated during the deposition of a thick copper layer is transcribed or enlarged onto a final semiconductor structure (see, e.g., FIG. 1A and FIG. 1B). Due to the increased use of polishing processes and the damage that occurs due to a polishing pad, a replace cycle of the polishing pad is shortened, thus increasing the cost of maintaining the CMP apparatus.

### SUMMARY OF THE INVENTION

The present invention provides a method of forming a conductive pattern. The method comprises (a) preparing a semiconductor substrate having a conductive pattern, (b) forming an interlayer dielectric pattern having an opening exposing the conductive pattern on the semiconductor substrate, (c) forming a metal layer on the interlayer dielectric pattern to fill the opening, (d) wet etching the metal layer, and (e) polishing the metal layer to form a metal pattern filling the opening. The step (d) is done such that a top surface of the interlayer dielectric pattern is not exposed.

In an exemplary embodiment of the present invention, the metal layer is made of a copper-containing metal. The metal layer is formed to a thickness ranging from 2 micrometers to 7 micrometers. The interlayer dielectric pattern is formed in step (b) from the group consisting of silicon oxide, fluorosilicate glass (FSG), carbon containing silicon oxide (SiOC), spin on glass (SOG), and porous dielectric.

The step (c) comprises (c1) forming a diffusion barrier layer covering an inner wall of the opening, (c2) forming a seed layer on the diffusion barrier layer, and (c3) forming a copper layer on the seed layer. The step (c1) is done by one selected from the group consisting of physical vapor deposition (PVD), chemical vapor deposition (CVD), atomic layer deposition (ALD), and metal organic CVD (MOCVD). The diffusion barrier layer is made of at least one selected from the group consisting of tantalum (Ta), tantalum nitride (TaN), titanium (Ti), titanium nitride (TiN), tungsten nitride (W₂N), and tantalum silicon nitride (TaSiN). The step (c2) is done by one selected from the group consisting of PVD, CVD, ALD, and MOCVD. The step (c3) is done by at least one selected from the group consisting of electrolytic plating, electroless plating, MOCVD, and PVD.

The step (c3) includes at least one deposition process and at least one annealing process. The step (d) is done using at least one etchant selected from the group consisting of hydrofluoric acid (HF), sulfuric acid (H₂SO₄), hydrogen peroxide (H₂O₂), de-ionized water (H₂O), tetramethylammonium hydroxide (TMAH), and combinations thereof. The step (d) is done such that the diffusion barrier layer is not exposed. The step (d) is done to allow the metal layer to remain with a thickness ranging from 0.1 micrometer to 2.0 micrometers.

In another exemplary embodiment of the present invention, the step (b) uses chemical mechanical polishing (CMP) and is done to expose the top surface of the interlayer dielectric pattern at an entire surface of the semiconductor substrate.

The step (b) comprises (b1) forming an interlayer dielectric on the semiconductor substrate including the conductive pattern and (b2) patterning the interlayer dielectric to form a trench where the metal pattern is disposed and a via hole connecting the metal pattern to the conductive pattern. For this, the interlayer dielectric may comprise a first etch-stop layer, a first interlayer dielectric, a second etch-stop layer, and a second interlayer dielectric. The first and second etch-stop layers may be made of either one of silicon nitride (SiN) and silicon carbide (SiC), and the first and second interlayer dielectrics may be made of at least one selected from the group consisting of silicon oxide (SiO₂), FSG, and low-k materials.

The step (b2) may employ a “via first dual damascene (VFDD) process”. The VFDD process comprises patterning the second interlayer dielectric, the second etch-stop layer, and the first interlayer dielectric from a top surface of the conductive pattern to the top surface of the first etch-stop layer to expose the first etch-stop and patterning the second interlayer dielectric, the second etch-stop layer, and the exposed first etch-stop layer to form a via hole exposing the top surface of the conductive pattern and a trench passing the via hole and exposing the top surface of the first interlayer dielectric. The step (b2) the interlayer dielectric is done using one selected from the group consisting of the VFDD process, trench first dual damascene (TFDD) process, and self-aligned dual damascene (SADD) process.

In another exemplary embodiment of the present invention a method of forming a metal pattern on a semiconductor substrate is provided. The method comprises: forming an interlayer dielectric pattern having an opening exposing a conductive pattern on the semiconductor substrate, wherein the step of forming an interlayer dielectric pattern comprises: forming an interlayer dielectric on the semiconductor substrate and patterning the interlayer dielectric using a VFDD process; forming a metal layer on the interlayer dielectric pattern to fill the opening; wet etching the metal layer, wherein a top surface of the interlayer dielectric is not exposed; and polishing the metal layer to form a metal pattern filling the opening. The step of forming a metal layer on the interlayer dielectric pattern comprises: forming a diffusion barrier layer covering an inner wall of the opening; forming a seed layer on the diffusion barrier layer; and forming a copper layer on the seed layer.

### BRIEF DESCRIPTION OF THE DRAWINGS

FIG. 1A and FIG. 1B are photographs of defects which occur during a conventional process of forming a copper pattern.

FIG. 2 through FIG. 5 are cross-sectional views for explaining a method of forming a conductive pattern of a semiconductor device according to a preferred embodiment of the present invention.

FIG. 6 through FIG. 11 are cross-sectional views for explaining a method of forming a conductive pattern of a semiconductor device according to another preferred embodiment of the present invention.

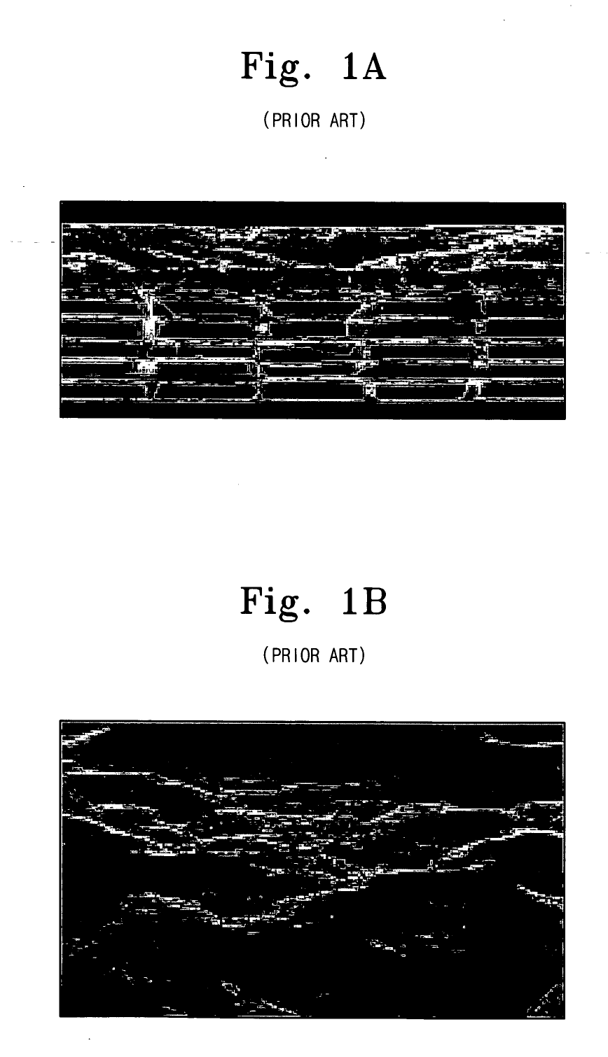

### DETAILED DESCRIPTION OF THE PREFERRED EMBODIMENTS

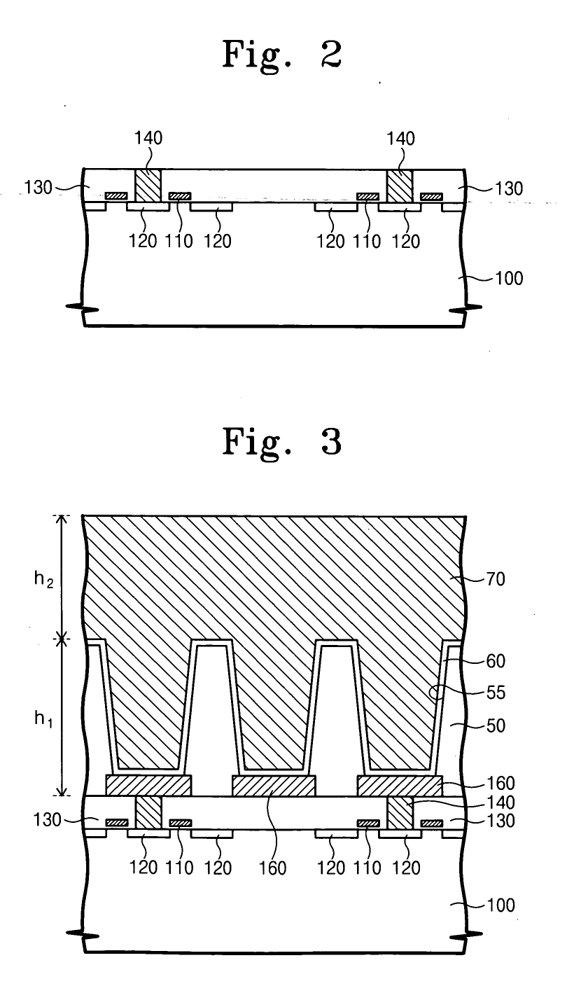

A method of forming a conductive pattern of a semiconductor device according to a preferred embodiment of the present invention will now be described with reference to FIG. 2 through FIG. 5.

Referring to FIG. 2, a plurality of metal oxide semiconductor (MOS) transistors are formed at a semiconductor substrate 100. The transistors include gate patterns 110 formed on the semiconductor substrate 100 and source/drain regions 120 formed in the semiconductor substrate 100 adjacent to the gate patterns 110. A lower interlayer dielectric pattern 130 is formed at the semiconductor substrate 100 including the transistors. The lower interlayer dielectric pattern 130 has a contact hole exposing the source/drain regions 120 at a predetermined region. A contact plug 140 is formed to fill the contact hole. The contact plug 140 is connected to the source/drain regions 120.

Referring to FIG. 3, a conductive pattern 160 is formed on the lower interlayer dielectric pattern 130 to be connected with the contact plug 140. An upper interlayer dielectric pattern 50 is formed over the semiconductor substrate 100 including the conductive pattern 160. The upper interlayer dielectric pattern 50 has an opening exposing a top surface of the conductive pattern 160 at a predetermined region. Preferably, the upper interlayer dielectric pattern 50 is made of at least one selected from the group consisting of silicon oxide, fluorosilicate glass (FSG), carbon containing silicon oxide (SiOC), spin on glass (SOG), and porous dielectric.

A diffusion barrier layer 60 is formed on an entire surface of the semiconductor substrate 100 including the upper interlayer dielectric pattern 50. As a result, the diffusion barrier layer 60 covers an inner sidewall of an opening 55, an exposed top surface of the conductive pattern 160, and a top surface of the upper interlayer dielectric pattern 50. A copper layer 70 is formed over an entire surface of the semiconductor substrate 100 including the diffusion barrier layer 60.

Preferably, the copper layer 70 is formed using an electrolytic plating process. The electrolytic plating process includes forming a copper seed layer on the diffusion barrier layer 60 and applying a voltage to the copper seed layer in a copper-ion-dissolved solution to plate a copper layer on the copper seed layer. To reduce a resistance of the plated copper layer, a predetermined heat treatment process may be performed at a temperature of about 200° C.

In an exemplary embodiment for forming an inductor of a radio frequency (RF) device, the copper layer 70 may be formed to a thickness of 2-7 micrometers. In this case, formation of the copper layer 70 is conducted through at least two deposition steps and/or multiple steps including a heat treatment step done between the two deposition steps.

Alternatively, the copper layer 70 may be formed by one selected from the group consisting of electroless plating, metal organic chemical vapor deposition (MOCVD), and physical vapor deposition (PVD). Different interconnection structures having conductive lines, interlayer dielectrics, and plugs may be disposed between the conductive pattern 160 and the contact plug 140.

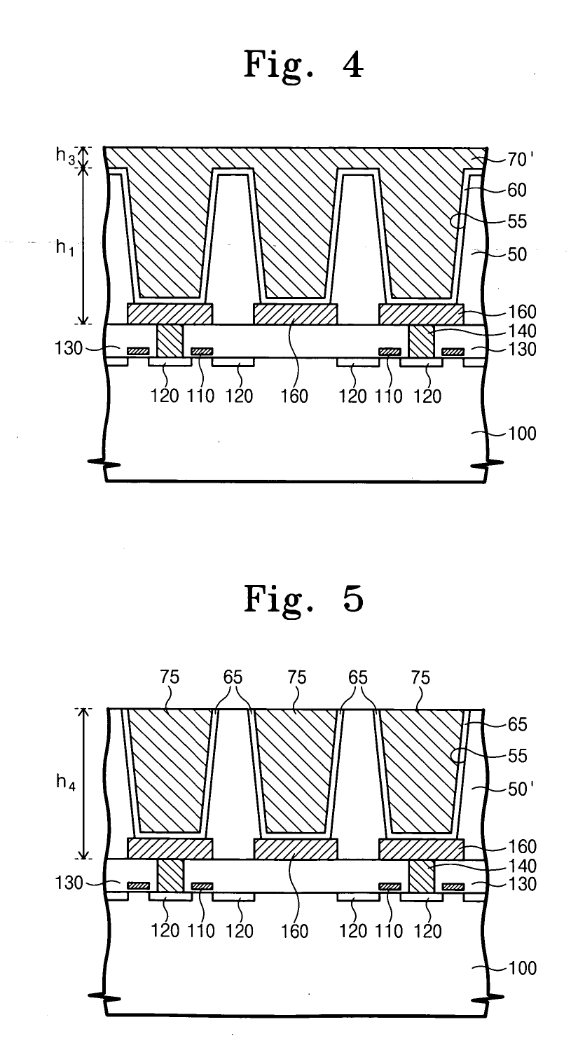

Referring to FIG. 4, the copper layer 70 is wet etched so that the diffusion barrier layer 60 may not be exposed, i.e., the copper layer 70 may remain on the upper interlayer dielectric pattern 50. Thus, a remaining copper layer 70′ having a thickness of about 1 micrometer is formed on the upper interlayer dielectric pattern 50. A thickness h₃ of the remaining copper layer 70′ may be regulated within a range from 0.1 micrometer to 2 micrometers when considering issues such as etch uniformity, etch rate, process efficiency, and so forth.

An etchant for etching the copper layer 70 may be at least one selected from the group consisting of hydrofluoric acid (HF), sulfuric acid (H₂SO₄), hydrogen peroxide (H₂O₂), de-ionized water (H₂O), tetramethylammonium hydroxide (TMAH), and combinations thereof. In an exemplary embodiment, a fluoric-peroxide mixture (FPM) solution containing HF, H₂O₂, and de-ionized water is used as an etchant for the copper layer 70. When the FPM solution is used, an etch rate of the copper layer 70 is proportional to the etch time and a ratio of the HF. Process parameters based on the etch properties may be regulated to enhance an efficiency of the wet etching process and etch quality. Particularly, in a copper etching process using a wet etchant, defects of the deposited copper layer are removed to enhance a quality of a subsequent process for polishing the copper layer.

Referring to FIG. 5, the remaining copper layer 70′ is polished to expose the upper interlayer dielectric pattern 50 throughout the wafer. By overpolishing the remaining copper layer 70′ and the diffusion barrier layer 60, a copper pattern 75, and a diffusion barrier pattern 65 are formed to fill the opening 55.

Preferably, polishing the copper layer 70 is conducted using a chemical mechanical polishing (CMP) process. Also, a polishing process for forming the copper pattern 75 includes two polishing steps. The remaining copper layer 70′ is polished in the first polishing step, and the diffusion barrier layer 60 is polished in the second polishing step. Preferably, the polishing process is performed so that a thickness h₄ of the upper interlayer dielectric pattern 50′ may be smaller than a thickness h₁ of the upper interlayer dielectric 50.

As described above, because the preferred embodiment of the present invention includes the wet etching step, excessive etching time, increased cost for maintaining a CMP apparatus, and drops in the productivity of the CMP apparatus, which arise when a thick copper layer is polished only using a conventional polishing technique, can be prevented. In addition, because the wet etching process may use a bath-type etch apparatus, dozens of wafers may be treated at the same time to shorten the etching time.

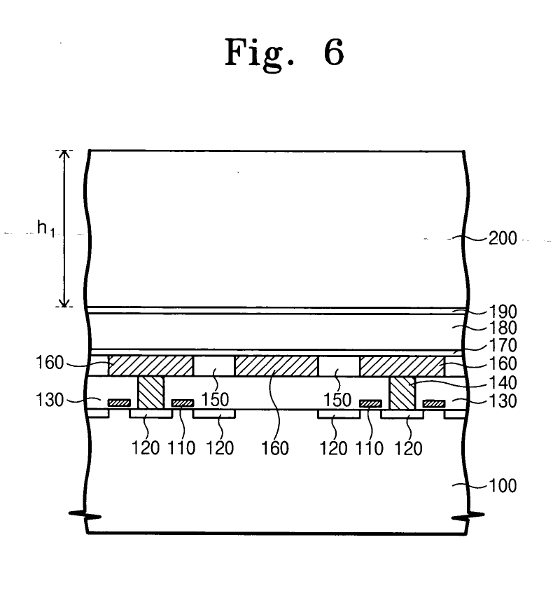

A method of forming a conductive pattern of a semiconductor device according to another preferred embodiment of the present invention will now be described with reference to FIG. 6 through FIG. 11. In this embodiment, a metal interconnection is formed using a dual damascene process. Because this embodiment includes technical contents similar to the embodiment described with reference to FIG. 2 through FIG. 5, the similar technical contents will not be described in further detail.

Although a via first dual damascene (VFDD) process will be described hereinafter, the present invention may be applied to various dual damascene processes such as a trench first dual damascene (TFDD) process, a self-aligned dual damascene (SADD) process, a modified TFDD process, and so forth.

Referring to FIG. 6, a gate pattern 110, source/drain regions 120, a lower interlayer dielectric pattern 130, and a contact plug 140 are formed at a semiconductor substrate 100, as previously described in FIG. 2. A conductive pattern 160 is formed to be connected with the contact plug 140.

A first etch-stop layer 170, a first interlayer dielectric 180, a second etch-stop layer 190, and a second interlayer dielectric 200 are sequentially formed on the semiconductor substrate 100 including the conductive pattern 160. The first and second etch-stop layers 170 and 190 are made of either one of silicon nitride (Si₃N₄) and silicon carbide (SiC). The first and second interlayer dielectrics 180 and 200 are made of at least one selected from the group consisting of silicon oxide (SiO₂), FSG, SOG, SiOC, and low-k materials.

An RF device to which the present invention is applicable has an inductor that is conventionally formed of a thick conductive pattern so as to obtain a higher quality factor (Q). The thickness of the conductive pattern is several micrometers. Because the conductive pattern used as the inductor is disposed in the second interlayer dielectric 200, the second interlayer dielectric 200 has a thickness h₁ corresponding to the thickness of the conductive pattern. Preferably, the thickness h₁ is determined in view of thickness loss from a subsequent polishing process.

For the RF device, the inductor is generally disposed at the highest layer in order to overcome a technical difficulty in the fabricating process which results from the thickness of the inductor. Therefore, at least one difference interconnection structure layer (not shown) having a conductive line, an interlayer dielectric, and a plug may be disposed between the conductive pattern 160 and the contact plug 140, as described above.

Prior to the formation of the first etch-stop layer 170, an insulation pattern 150 may be formed to fill a space between the conductive patterns 160. In this case, the first etch-stop layer 170 covers top surfaces of the insulation pattern 150 and the conductive patterns 160.

Referring to FIG. 7, the first etch-stop layer 170, the first interlayer dielectric 180, the second etch-stop layer 190, and the second interlayer dielectric 200 are patterned to form a first etch-stop pattern 175, a second etch-stop pattern 195, a first interlayer dielectric pattern 185, and a second interlayer dielectric pattern 205. The first etch-stop pattern 175 and the first interlayer dielectric pattern 185 make a via hole 210 exposing the top surface of the conductive pattern 160 at a predetermined region. The second etch-stop pattern 195 and the second interlayer dielectric pattern 205 make a trench 215 crossing over the via hole 210. The trench 215 is a gap region where an interconnection, particularly a conductive pattern for an inductor is to be disposed in a subsequent process.

There may be various methods of forming the via hole 210 and the trench 215. The VFDD process is one of the various methods. The VFDD process will now be explained in further detail. The second interlayer dielectric 200, the second etch-stop layer 190, and the first interlayer dielectric 180 are patterned to form the via hole 210 exposing a top surface of the first etch-stop layer 170 at the top of the conductive pattern 160. Namely, in this step, the first etch-stop layer 170 remains at a bottom surface of the via hole 210.

A photoresist pattern is formed to define the trench 215. Using the photoresist pattern as an etching mask, the second interlayer dielectric 200 adjacent to the via hole 210, the second etch-stop layer 190, and the first etch-stop layer 170 exposed in the via hole 210 are etched to form the via hole 210 exposing the conductive pattern 160 and the trench 215 passing over the via hole 210.

Due to the first etch-stop layer 170, the conductive pattern 160 is not damaged while the first interlayer dielectric 180 is etched to form the trench 215. For this reason, the first etch-stop layer 170 is made of a material having a similar etch rate to that of the second etch-stop layer 190 but having a low etch rate with respect to an etchant used in a process for etching the second and first interlayer dielectrics 200 and 180.

A high diffusivity of copper is known to result in the degradation of transistor characteristics. Therefore, a copper pattern is generally surrounded by a conductive or insulation diffusion barrier layer in a final semiconductor structure.

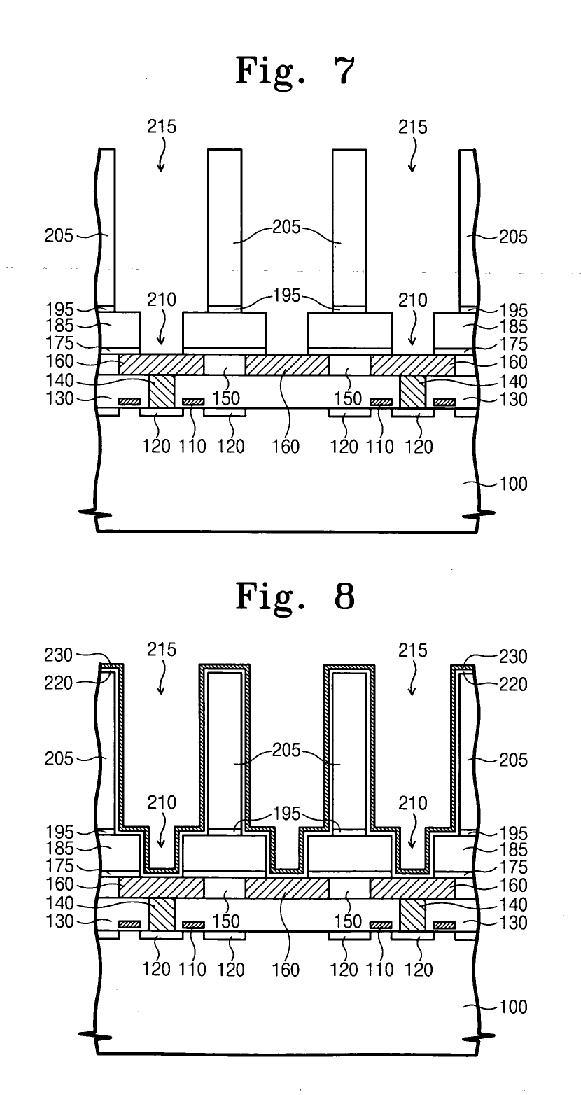

Referring to FIG. 8, a diffusion barrier layer 220 is formed on an entire surface of the semiconductor substrate 100 where the trench 215 and the via hole 210 are formed. The diffusion barrier layer 220 serves to prevent the contamination and diffusion of copper. In order to minimize layer separation and electromigration (EM), the diffusion barrier layer 200 must have a super adhesive force to bind to copper. For this, the diffusion barrier layer 220 is made of at least one selected from the group consisting of tantalum (Ta), tantalum nitride (TaN), titanium (Ti), titanium nitride (TiN), tungsten nitride (W₂N), silicon nitride, and tantalum silicon nitride (TaSiN). Preferably, the diffusion barrier layer 220 is made of Ta/TaN. In the case where the diffusion barrier layer 220 is an insulation layer made of silicon nitride, a subsequent process for removing the silicon nitride layer from the top of the conductive pattern 160 is added.

Formation of the diffusion barrier layer 220 may be conducted using physical vapor deposition (PVD) including sputtering. But chemical vapor deposition (CVD), atomic layer deposition (ALD), and MOCVD may be used.

The VFDD process for use with the present invention employs an electrolytic plate technique to form a copper layer. In accordance with the electrolytic plating technique, after a seed layer to be used as an electrode is formed on a semiconductor substrate, a copper layer is formed on the seed layer by electrolysis.

According to the electrolytic plating technique, a seed layer 230 is formed on the diffusion barrier layer 220. The formation of the seed layer 230 is conducted using one selected from the group consisting of PVD, CVD, ALD, and MOCVD.

On the other hand, a copper layer may be formed by an electroless plating technique. In this case, formation of the seed layer 230 may be omitted. The diffusion barrier layer 220 may be made of tungsten nitride (W₂N).

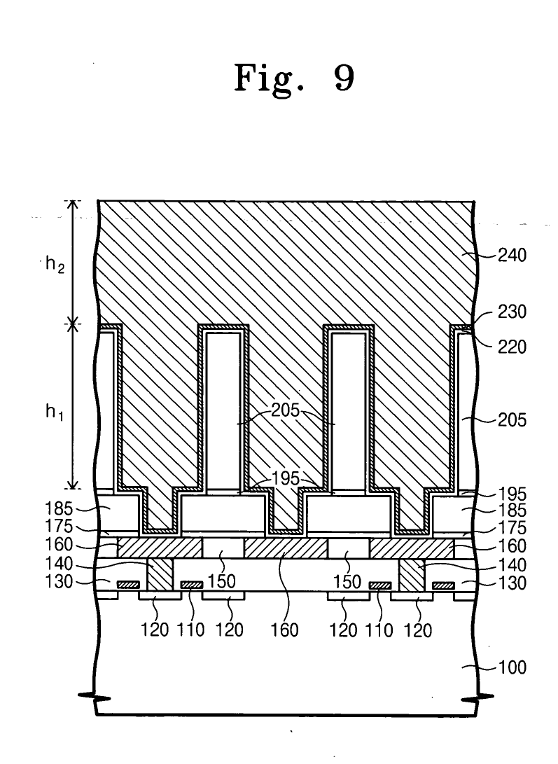

Referring to FIG. 9, a copper layer 240 is formed on the seed layer 230. Preferably, the formation of the copper layer 240 is conducted using the electroless plating method using the seed layer 230 as an electrode. Alternatively, the seed layer 230 is formed using the electroless plating method.

A typical semiconductor may have a trench having a low aspect ratio like a capacitor having a large width. In this case, a copper layer having a proper thickness to bury a trench of a high aspect ratio may not fill the trench of the small aspect ratio. In view of the foregoing, the copper layer 240 has a thickness which is enough to fully fill the trenches 215 (shown empty in FIGS. 7 and 8 and filled in FIG. 9) having a variety of aspect ratios. Particularly, in the case of an RF device having an inductor, a thickness h₂ of the copper layer 240 may have a thickness ranging from 2 micrometers to 7 micrometers, as previously stated.

Likewise, a method of forming the copper layer 240 includes two deposition processes and an annealing process performed therebetween. A first deposition process uses the electrolytic plating, and a second deposition process uses one selected from the group consisting of electrolytic plating, electroless plating, MOCVD, and PVD. In the annealing process, the copper layer deposited in the first deposition process is crystallized to reduce its resistance. The copper layer deposited in the second deposition process may grow with a crystalline structure on the annealed copper layer. In this case, it is not necessary to perform an additional annealing process after the second deposition process is performed.

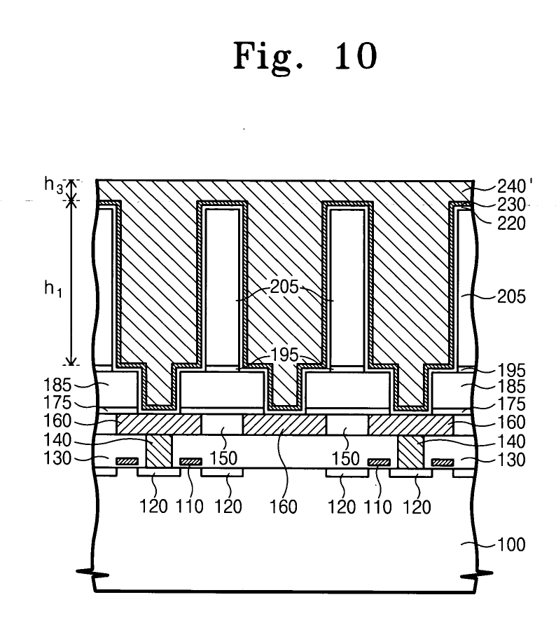

Referring to FIG. 10, the copper layer 240 is wet etched such that the seed layer 230 is not exposed. As a result, a remaining copper layer 240′ remains on the second interlayer dielectric pattern 205. Preferably, the remaining copper layer 240′ has a thickness ranging from 0.1 micrometer to 2.0 micrometers. The copper layer 240 is wet etched as described above with reference to FIG. 2 through FIG. 6.

In the case where the diffusion barrier layer 220 or the seed layer 230 is exposed during the wet etching process, a used etchant causes chemical damage such as corrosion of the seed layer 230 or the diffusion barrier layer 220. When an FPM solution containing H₂O₂ is used as the etchant, the chemical damage becomes more serious. Due to the wet etching process, defects of the copper layer 240 are obviated and a top surface of the copper layer 240 is somewhat planarized. Nevertheless, because the wet etching process has an intrinsic isotropic etch characteristic, a resultant semiconductor and/or wafer structure having a perfect planarity cannot be obtained only by the wet etching process. Therefore, the wet etching process is performed to allow the copper layer 240′ to remain on the second interlayer dielectric pattern 205, as described above. The remaining copper layer 240′ is then planarized in a polishing process offering superior planarity.

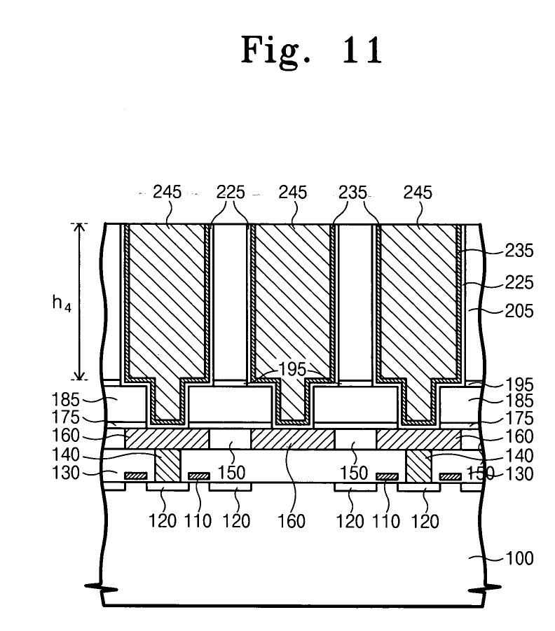

Referring to FIG. 11, the remaining copper layer 240′ is polished down to a top surface of the second interlayer dielectric pattern 205 to form a diffusion barrier pattern 225, a seed layer pattern 235, and a copper pattern 245 which sequentially cover an inner wall of the trench 215. Preferably, the remaining copper layer 240′ is polished using the CMP process. Preferably, the CMP process is performed so that a thickness h₄ of the second interlayer dielectric pattern 205 may be smaller than the thickness h₁ of the initially deposited upper interlayer dielectric 200. The other procedures associated with the polishing process are similar to those described for FIG. 2 through FIG. 5 and will not be described in further detail.

Because the thickness of the copper layer 240 is reduced by the wet etching process, the time required for the polishing process is shortened. Further, the defects of the deposited copper layer 240 are obviated by the wet etching process, thus improving a quality of the polishing process. The improvement in quality may prevent the damage that typically occurs to a polishing pad. Moreover, the burden of the polishing process is eased, thus reducing the maintenance of a polishing apparatus (e.g., replacement of a worn-out polishing pad).

Although the present invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

1. A method of forming a conductive pattern, comprising:
(a) preparing a semiconductor substrate having a conductive pattern;
(b) forming an interlayer dielectric pattern having an opening exposing the conductive pattern on the semiconductor substrate;
(c) forming a metal layer on the interlayer dielectric pattern to fill the opening;
(d) wet etching the metal layer; and
(e) polishing the metal layer to form a metal pattern filling the opening,
wherein the step (d) is done such that a top surface of the interlayer dielectric pattern is not exposed.

2. The method as recited in claim 1, wherein the metal layer is made of a copper-containing metal.

3. The method as recited in claim 2, wherein the step (c) comprises:
(c1) forming a diffusion barrier layer covering an inner wall of the opening;
(c2) forming a seed layer on the diffusion barrier layer; and
(c3) forming a copper layer on the seed layer.

4. The method as recited in claim 3, wherein the step (c1) is done by one selected from the group consisting of physical vapor deposition (PVD), chemical vapor deposition (CVD), atomic layer deposition (ALD), and metal organic CVD (MOCVD).

5. The method as recited in claim 3, wherein the diffusion barrier layer is made of one selected from the group consisting of tantalum (Ta), tantalum nitride (TaN), titanium (Ti), titanium nitride (TiN), tungsten nitride (W₂N), and tantalum silicon nitride (TaSiN).

6. The method as recited in claim 3, wherein the step (c2) is done by one selected from the group consisting of PVD, CVD, ALD, and MOCVD.

7. The method as recited in claim 3, wherein the step (c3) is done by one selected from the group consisting of electrolytic plating, electroless plating, MOCVD, and PVD.

8. The method as recited in claim 3, wherein the step (c3) includes one of a deposition process and an annealing process.

9. The method as recited in claim 1, wherein the metal layer is formed to a thickness ranging from 2 micrometers to 7 micrometers.

10. The method as recited in claim 1, wherein the step (d) is done using one etchant selected from the group consisting of hydrofluoric acid (HF), sulfuric acid (H₂SO₄), hydrogen peroxide (H₂O₂), de-ionized water (H₂O), and tetramethylammonium hydroxide (TMAH).

11. The method as recited in claim 3, wherein the step (d) is done such that the diffusion barrier layer is not exposed.

12. The method as recited in claim 1, wherein the step (b) uses chemical mechanical polishing (CMP) and is done to expose the top surface of the interlayer dielectric pattern at an entire surface of the semiconductor substrate.

13. The method as recited in claim 11, wherein the step (d) is done to allow the metal layer to remain with a thickness ranging from 0.1 micrometer to 2.0 micrometers.

14. The method as recited in claim 1, wherein the step (b) comprises:
(b1) forming an interlayer dielectric on the semiconductor substrate including the conductive pattern; and
(b2) patterning the interlayer dielectric to form a trench where the metal pattern is disposed and a via hole connecting the metal pattern to the conductive pattern.

15. The method as recited in claim 14, wherein the step (b1) comprises forming a first etch-stop layer, a first interlayer dielectric, a second etch-stop layer, and a second interlayer dielectric to cover a top surface of the conductive pattern,
the first and second etch-stop layers being made of one of a silicon nitride (SiN) and silicon carbide (SiC); and
the first and second interlayer dielectric being made of one selected from the group consisting of silicon oxide (SiO₂), FSG, and low-k material.

16. The method as recited in claim 15, wherein the step (b2) comprises:
patterning the second interlayer dielectric, the second etch-stop layer, and the first interlayer dielectric to expose the first etch-stop layer on the conductive pattern; and
patterning the second interlayer dielectric, the second etch-stop layer, and the exposed first etch-stop layer to form a via hole exposing the top surface of the conductive pattern and a trench passing the via hole and exposing the top surface of the first interlayer dielectric.

17. The method as recited in claim 15, wherein the step (b2) is done using one selected from the group consisting of a via first dual damascene (VFDD) process, trench first dual damascene (TFDD) process, and self-aligned dual damascene (SADD) process.

18. The method as recited in claim 1, wherein the interlayer dielectric pattern is formed in step (b) from the group consisting of silicon oxide, fluorosilicate glass (FSG), carbon containing silicon oxide (SiOC), spin on glass (SOG), and porous dielectric.

19. A method of forming a metal pattern on a semiconductor substrate, comprising:
forming an interlayer dielectric pattern having an opening exposing a conductive pattern on the semiconductor substrate, wherein the step of forming an interlayer dielectric pattern comprises:
forming an interlayer dielectric on the semiconductor substrate and patterning the interlayer dielectric using a via first dual damascene (VFDD) process;
forming a metal layer on the interlayer dielectric pattern to fill the opening;
wet etching the metal layer, wherein a top surface of the interlayer dielectric is not exposed; and
polishing the metal layer to form a metal pattern filling the opening.

20. The method as recited in claim 19, wherein the step of forming a metal layer on the interlayer dielectric pattern comprises:
forming a diffusion barrier layer covering an inner wall of the opening;
forming a seed layer on the diffusion barrier layer; and
forming a copper layer on the seed layer.
